(19) United States
(12) Patent Application Publication
(10) Pub. No.: US 2025/0183905 A1
(43) Pub. Date: Jun. 5, 2025

(54) MULTI-STAGE PIPELINE SAR ANALOG-TO-DIGITAL CONVERTER (ADC)

(71) Applicant: ARCTIC SEMICONDUCTOR CORPORATION, San Jose, CA (US)

(72) Inventors: Yahya TOUSI, Minnetonka, MN (US); Vahid M TOOSI, Los Altos, CA (US)

(73) Assignee: ARCTIC SEMICONDUCTOR CORPORATION, San Jose, CA (US)

(21) Appl. No.: 18/530,066

(22) Filed: Dec. 5, 2023

(51) Int. Cl. H03M 1/10

(52) U.S. Cl. CPC H03M 1/1014

(57) ABSTRACT

A multi-stage pipeline successive approximation register (SAR) analog-to-digital converter (ADC) is disclosed. The processing stages quantize an analog input signal by a predetermined number of bits. A first processing stage quantizes the analog input signal and determines a first analog residue signal based on the difference between sampled instances of the analog input signal and corresponding quantized values. The subsequent stages continue this quantization, generating further analog residues by comparing sampled residues to their quantized forms. The data converter employs a sequence of operational modes to facilitate conversion of the analog input signal to a digital output signal.

### BACKGROUND

### Field of the Art

The present invention relates generally to analog-to-digital converters (ADCs), and more specifically, to a multi-phase pipeline Successive Approximation Register (SAR) ADC architecture that offers enhanced speed, resolution, and power efficiency.

### Discussion of the State of the Art

Analog-to-digital converters (ADCs) play a pivotal role in various electronic applications by converting analog signals into their respective digital forms. The speed and accuracy of this conversion process can directly influence the performance of systems in which these ADCs are employed. Previous approaches to data converters have involved various techniques for quantizing analog input signals to generate digital output signals.

One such approach is the use of successive approximation techniques, where the analog input signal is compared to a reference voltage and the quantization is performed iteratively by adjusting the reference voltage based on the comparison results. However, these approaches often suffer from limitations in terms of speed, accuracy, and power consumption. One known approach to augment the speed of data converters is time interleaving, where multiple ADCs operate in parallel. Yet, while it does increase the speed, it multiplies the channels, potentially complicating the system and consuming more space.

A need thus remains for an ADC architecture that can efficiently bridge the gap between speed, resolution, and power consumption without necessarily multiplying the number of channels or significantly increasing the area.

### BRIEF DESCRIPTION OF THE DRAWINGS

In order to describe the manner in which the above-recited and other advantages and features of the disclosure can be obtained, a more particular description of the principles briefly described above will be rendered by reference to specific embodiments thereof which are illustrated in the appended drawings. Understanding that these drawings depict only exemplary embodiments of the disclosure and are not therefore to be considered to be limiting of its scope, the principles herein are described and explained with additional specificity and detail through the use of the accompanying drawings in which:

FIG. 1A illustrates an example of a multi-phase pipeline successive approximation register (SAR) ADC architecture in which aspects of the various embodiments can be implemented.

FIG. 1B illustrates an example of an internal architecture of a stage in accordance with various embodiments.

FIG. 2 illustrates an example of a circuit-level schematic of an architecture in which aspects of the various embodiments can be implemented.

FIG. 3A illustrates an example of operational timing of a three-phase SAR data converter in accordance with various embodiments.

FIG. 3B illustrates an example process for a three-phase SAR data converter in accordance with various embodiments.

FIG. 4 illustrates an example of a binary search algorithm for the successive approximation register (SAR) quantization process in accordance with various embodiments.

FIG. 5 illustrates an exemplary computing device that can be utilized in accordance with various embodiments; and

FIG. 6 illustrates example components of a computing device, such as the computing device illustrated in FIG. 5.

### DETAILED DESCRIPTION

Systems and methods in accordance with various embodiments of the present disclosure may overcome one or more of the aforementioned and other deficiencies experienced in conventional analog-to-digital converters (ADCs). In particular, various embodiments describes multi-phase pipeline successive approximation register (SAR) ADC architecture to correct and calibrate non-idealities in ADCs.

In accordance with various embodiments, a multi-phase pipeline SAR ADC architecture separates the conversion process into several distinct phases. Each of these phases is managed by its own pipeline stage. Within this design, certain components, including, e.g., switches and capacitors, are used multiple times to facilitate parallel operation of three modes: sampling (“S” mode), successive approximation (“R” mode), and amplify/hold (“H” mode). By doing so, the ADC can concurrently process data across three phases (e.g., PH1, PH2, and PH3), significantly boosting the speed of conversion. This approach allows the data converter to increase its quantization speed without a notable rise in power consumption.

In certain embodiments, integrated within this architecture are specific algorithms tailored to calibrate and rectify any internal imperfections of the ADC, ensuring that the analog signals are converted to their digital versions accurately, e.g., to a threshold level of accuracy, considering any possible deviations due to hardware shortcomings or other external factors.

The disclosed multi-phase pipeline Successive Approximation Register (SAR) ADC architecture provides several advantages in analog-to-digital conversion. Specifically, approaches described herein archive improved conversion speed through parallel processing across multiple stages, eliminating or at least reducing the need for additional channels. Systems and methods of systematic sequencing of operations yield improved resolution, ensuring accurate conversion of analog signals to digital counterparts. Systems and methods allow for integration into various electronic systems without expanding channels. Additionally, the architecture is designed for adaptability, allowing modifications to meet different operational requirements, such as bit resolution or conversion speed adjustments.

Various other functions and advantages are described and suggested below as may be provided in accordance with the various embodiments.

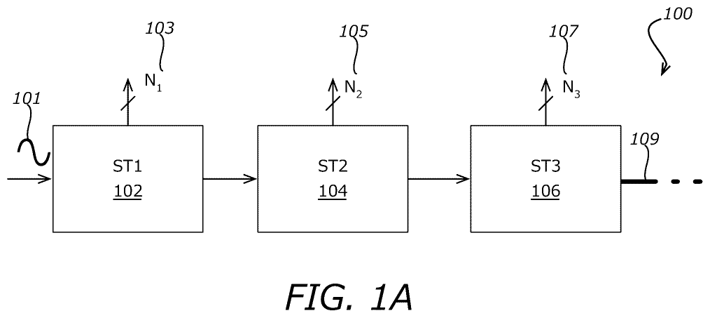

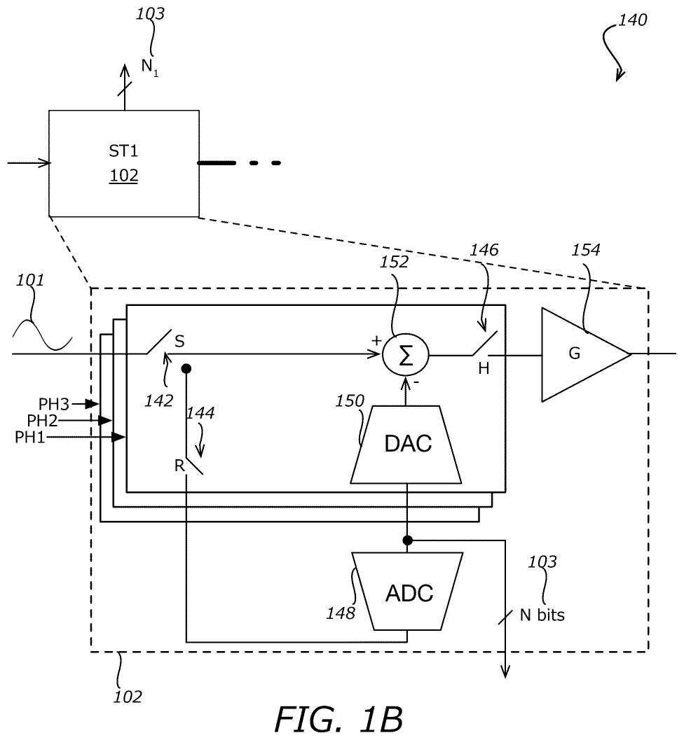

FIG. 1A illustrates example 100 of a multi-phase pipeline successive approximation register (SAR) ADC architecture in which aspects of the various embodiments can be implemented. In accordance with various embodiments, the architecture is operable to process an incoming analog signal, designated as input signal 101 through multiple processing stages-specifically a first stage 102, a second stage 104, and a third stage 106—to generate a digitized output signal.

In an embodiment, input signal 101 comprises an analog signal that may originate from various sources, including, e.g., continuous-time signals. Input signal 101 is received by the architecture at first stage 102 for initial quantization. The output signal is a digitized version of the input signal 101, generated as a result of processing across the multiple stages of the architecture.

In an embodiment, each stage, beginning with the first stage 102, quantizes an input signal by a predetermined number of bits, calculates the analog residue (e.g., difference between sampled and quantized signals), and amplifies this residue for subsequent stages. The sum of the bits collected from individual stages provides the total bit-depth of the digitized output signal.

Stage 102, further described in FIG. 1B, receives input signal 101 and quantizes input signal 101 to generate a quantized signal represented by 103. In an embodiment, quantized signals may be referred to as, for example, inter-stage signals. In various embodiments, an inter-stage signal may represent quantized values of respective input signals and act as a link for relaying information, specifically analog residues, to subsequent stages.

The quantization process may involve methods such as successive approximation register (SAR) or other suitable methods. In various embodiments, the quantization process involves taking discrete-time samples of the input signal 101 and comparing these with reference signals to generate the quantized values that constitute signal 103. In various embodiments, a differential comparator (e.g., differential comparator 152 in FIG. 1B), facilitates the quantization process. A resulting signal, termed the “first analog residue signal,” is derived as the difference between these sampled instances of input signal 101 and their corresponding quantized values in signal 103. This first analog residue signal is amplified for further processing and available to the input of the next stage, e.g., stage 104, for further processing.

The second stage, e.g., stage 104, receives the first analog residue signal from stage 102. The first analog residue signal, now the input signal to stage 104, is quantized, the quantized signal represented by 105. In certain embodiments, filtering functions may be incorporated into this stage prior to quantization. The difference between a sample signal of the first analog residue signal and a quantized version of the first analog residue signal is determined. An analog residue of the first analog residue signal (also referred to as a second analog residue signal) is amplified and available to the input of stage 106.

Stage 106 receives the second analog residue signal from stage 104. The second analog residue signal, now the input signal to stage 106, is quantized by a number of bits, the quantized signal represented by 107. In specific embodiments, noise reduction techniques may be integrated into this stage. The difference between a sample signal of the second analog residue signal and a quantized version of the second analog residue signal is determined. An analog residue of the second analog residue signal (also referred to as a third analog residue signal) is amplified and provided as output 109. The quantized values from signal 107 are combined with those of preceding stages, specifically signals 103 and 105, to compile the comprehensive digital output signal, suitable for various digital computing applications.

In certain embodiments, the individual stages utilize calibration techniques to offset any inherent non-linearity or inaccuracies that might affect the overall digitization quality. Such calibrations, although not shown explicitly in FIG. 1A, could involve feedback mechanisms or self-learning algorithms to continually enhance the ADC's performance.

FIG. 1B illustrates example 140 of an internal architecture of a stage in accordance with various embodiments. In this example, stage 102, and the other stages, is configured to operate under three parallel phases: PH1, PH2, and PH3. These phases facilitate simultaneous Sample(S), Successive Approximation (R), and Amplify/Hold (H) operations. In an embodiment, each of these phases-PH1, PH2, and PH3-incorporates components such as sample switch(S) 142, successive approximation switch (R) 144, digital-to-analog converter (DAC) 150, amplify/hold switch (H) 146, and differential comparator 152.

Within each phase, sample switch(S) 142 captures the input signal (e.g., input signal 101), and its output is connected to both successive approximation switch (R) 144 and differential comparator 152. Successive approximation switch (R) 144 provides its output to quantizer block (ADC) 148, which transforms the analog signal into a digital form. The DAC 150 subsequently calculates the difference between the sampled and quantized signals in a multi-step process.

Differential comparator 152, in certain embodiments, evaluates the output from DAC 150 and provides the output to amplify/hold switch (H) 146. Amplify/hold Switch (H) 146 is connected to amplifier 154 (e.g., an operational amplifier), which amplifies the residue signals, eventually providing them into the next stage for further quantization.

In an embodiment, ADC 148 and amplifier 154 are shared resources across phases PH1, PH2, and PH3. This architecture allows for an efficient utilization of power-consuming modules without requiring their duplication. In accordance with various embodiments, the operation of these shared components is time-multiplexed across the different operational modes in each phase. For example, when PH1 is in the S mode, PH2 is in the R mode, and PH3 is in the H mode.

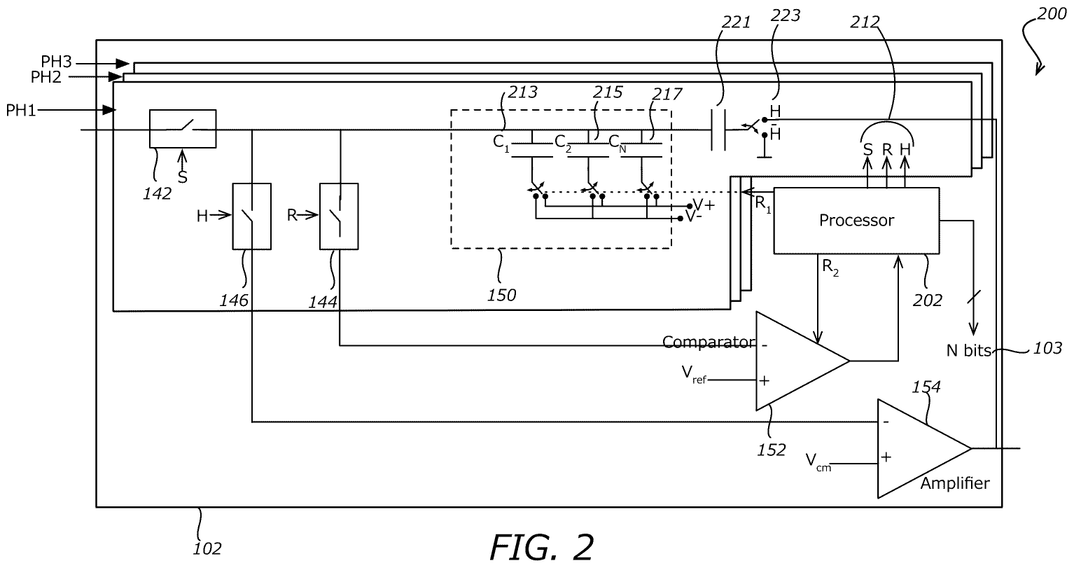

FIG. 2 illustrates example 200 of a circuit-level schematic of an architecture in which aspects of the various embodiments can be implemented. In an embodiment, FIG. 2 shows the connections of R switch 144, S switch 142, and H switch 146 in more detail.

In this embodiment, each operational phase—PH1, PH2, and PH3—includes a series of switched capacitors denoted as C₁ (213), C₂ (215), up to C_{N} (217). These switched capacitors, in conjunction with state machine processing unit 202, function collectively to constitute the Digital-to-Analog Converter (DAC) 150. State machine processing unit 202 drives a set of switches through its output labeled “R₁”. Each of these switches is connected to one side of capacitors C₁ (213), C₂ (215), and C_{N} (217). Depending on the iterative binary output from the state machine, each switch selectively connects its corresponding capacitor to a positive reference voltage (V+) or a negative reference voltage (V−).

It should be noted that the number of capacitors used herein can vary based on design needs, desired resolution, or specific application requirements. For example, in scenarios where a higher resolution is desired, more capacitors might be incorporated, allowing for a more detailed approximation of the analog signal. Conversely, fewer capacitors could be utilized for applications where a quicker, albeit potentially less precise, conversion is sufficient.

The state machine processing unit 202 performs binary search quantization in N steps, thereby converting the analog input into a digital form consisting of N bits. If N is equal to 8, for example, the state machine processing unit 202 would perform eight iterations of binary search. During each iteration, it adjusts one of the eight bits in the digital output, starting from the most significant bit (MSB) to the least significant bit (LSB), until a digital output that closely approximates the original analog input is obtained.

It should be noted that State machine processing unit 202 has three distinct outputs labeled as R₁, R₂, and R₃ serving different functionalities in the architecture, where R₁ is the output from state machine processing unit 202 that drives the set of switches, R₂ is the output provided to comparator 152, and R₃ is used to coordinate the operational modes for PH1, PH2, and PH3. In the architecture depicted in FIG. 2, the output labeled R₂ from state machine processing unit 202 serves a function in the operation of comparator 152. Specifically, R₂ represents a reference signal or threshold value against which an analog input, or its derived version, is compared during the quantization process. At each quantization step, comparator 152 contrasts the analog residue with this R₂ reference. The outcome of this comparison dictates the adjustments made to the forming digital approximation within the state machine processing unit 202. For example, if the analog residue surpasses R₂, the corresponding bit in the digital output is set to ‘1’. Conversely, if the analog residue is less than or matches R₂, the bit is marked as ‘0’. This iterative process ensures an accurate and precise digital output corresponding to the original analog signal.

State machine processing unit 202 is operable to generate control signals, identified as 212, to coordinate the operational modes for PH1, PH2, and PH3. These control signals allow for parallel operation of the three phases, thus optimizing the system's resource utilization.

In certain embodiments, the sequence of operational modes—comprising a sampling mode, a successive approximation mode, and an amplify/hold mode—as applied during the conversion process of the analog input signal to the digital output signal, can be dynamically adjusted or fine-tuned based on specific characteristics of the received analog input signal.

For example, the system can employ algorithms or logic operations that analyze the characteristics of the analog input signal, such as its amplitude, frequency, and phase. By considering these characteristics, the system may determine the optimal sequence or duration of the operational modes to ensure that the analog-to-digital conversion process is fine-tuned for that specific signal. For example, a high-frequency analog signal might require adjustments to the sampling mode's duration to accurately capture the signal's nuances, or a low amplitude signal may benefit from an extended amplify/hold mode to enhance the signal's clarity.

By dynamically adjusting the operational modes based on the characteristics of the analog input signal, the system can enhance specific performance metrics. These performance metrics can encompass various aspects of the conversion process, such as the level of accuracy or efficiency. The level of accuracy can refer to the fidelity of the digital output signal relative to the analog input signal, ensuring that the converted digital representation is as close as possible to the original analog form. On the other hand, efficiency can refer to the speed of conversion or power consumption metrics, ensuring that the data converter optimally utilizes its resources.

Such dynamic adjustments can be orchestrated by dedicated processing units or controllers that are equipped with the necessary algorithms. These units can continually monitor the incoming analog signals, assess their characteristics, and make real-time adjustments to the operational modes, thereby ensuring that the data converter's performance is continually optimized for the specific signals it encounters.

Differential comparator 152 compares the analog residue with a reference voltage (Vref) at each quantization step. State machine processing unit 202 adjusts the corresponding capacitor to increase or decrease the residue value for subsequent quantization. In an example, when the analog residue is higher than the reference voltage, differential comparator 152 signals state machine processing unit 202 to adjust capacitor C₁ (213), thereby reducing the analog residue value. This adjusted residue is provided into the subsequent stage, such as stage 104, for further quantization. The interaction of differential comparator 152 with state machine processing unit 202 ensures a precise and adaptive quantization process, facilitating a more accurate digital representation of the original analog signal.

In an embodiment, capacitor 221 and H transistor/switch 223 can form a sample-and-hold circuitry. Capacitor 221 and H transistor/switch 223 are operable to sample the incoming analog signal and maintain its value during the conversion process.

After quantization in stage 102, a first analog residue signal is generated. Amplifier 154 and H-switch 146 amplify the residue, preparing it for the next processing stage. For example, after quantization in stage 102, a first analog residue signal is generated. H-switch 146 directs this residue signal to amplifier 154, which amplifies the signal by a factor of ‘A.’ A common-mode voltage, V_{cm}, is provided to the positive input of amplifier 154 to set the operational point of the amplifier. This amplified first analog residue signal is then routed as the input to the subsequent stage, stage 104, for further processing. The amplification process allows for a higher signal-to-noise ratio, ensuring better data integrity as the signal progresses through multiple stages.

FIG. 2 further illustrates the architecture's capability for parallel processing through the three operational phases, PH1, PH2, and PH3. A subset of components, including the switches and capacitors, is replicated three times. This allows Sample(S), Successive Approximation (R), and Amplify/Hold (H) to occur simultaneously. This parallel processing increases the speed of quantization without significantly increasing power consumption.

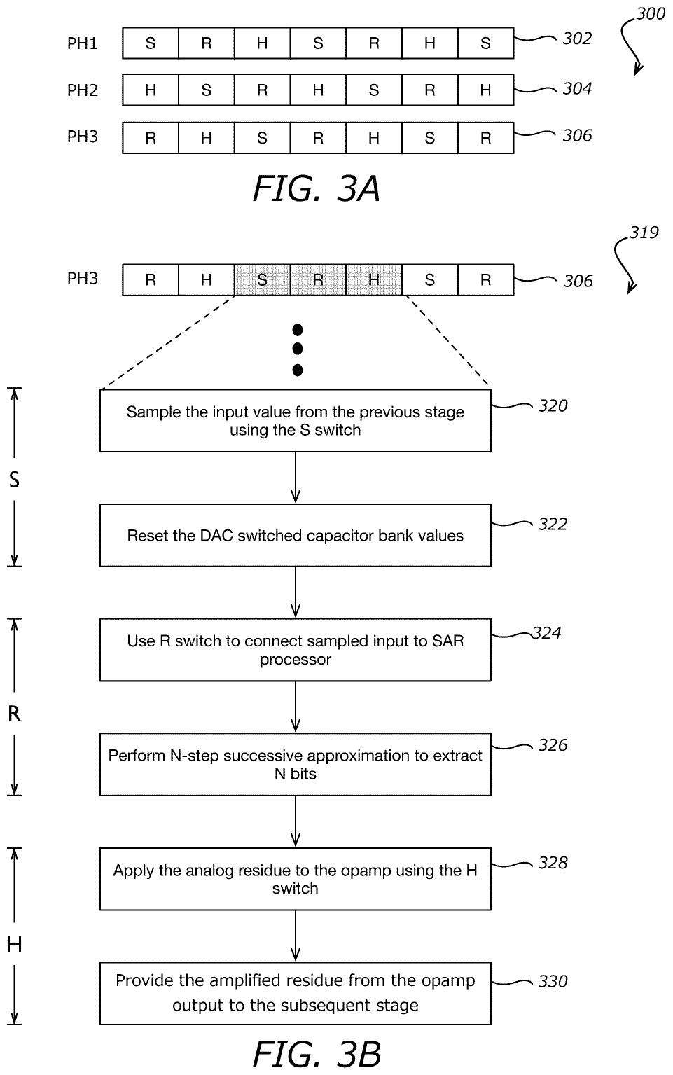

FIG. 3A illustrates example 300 illustrating operational timing of a three-phase SAR data converter in accordance with various embodiments. As described, through the interleaved operation of these phases, embodiments described herein enable parallel processing, thus increasing data conversion speed without a corresponding rise in power consumption. The control signals 212 for these phases, as generated by state machine processing unit 202, facilitate this parallel operation, reinforcing the efficient utilization of hardware resources.

In this example, FIG. 3A shows how each operational phase—PH1 302, PH2 304, and PH3 306—conducts its own sample(S), successive approximation (R), and amplify/hold (H) processes. The sequential and overlapping actions of these phases ensure that there is no idle time, optimizing the conversion process. This operational timing correlates with the circuit architecture explained in FIG. 2 and provides an efficient system for digital signal conversion.

In an embodiment, each phase operates in a distinct mode at any given time to optimize component utilization. For example, when PH1 302 is in the S mode, PH2 304 is conducting operations in the R mode, and PH3 306 is active in the H mode. This arrangement is particularly efficient for power-intensive components like amplifier 154, differential comparator 152, and state machine processing unit 202, which were detailed in FIG. 2.

In another example, if PH1 302 is sampling the input signal as previously elaborated, state machine processing unit 202 would be sending the control signals to adjust the most significant bit (MSB) in this phase. Simultaneously, PH2 304 could be in R mode, where state machine processing unit 202 is performing binary search and differential comparator 152 is performing a comparison of the analog residue against a reference voltage, enabling state machine processing unit 202 to adjust the corresponding capacitor value, such as C1, as indicated in FIG. 2.

Amplifier 154 plays a role during the H mode in PH3 306. For instance, it amplifies the residue signal generated after quantization in a previous stage, like stage 102. This amplified residue is then used as the input for the next processing stage, contributing to an enhanced signal-to-noise ratio and improving data integrity. Additionally, this approach ensures that the amplified residue maintains a consistent quality as it moves through the stages, minimizing errors and potential loss of data accuracy.

FIG. 3B illustrates example 319 of a process for a three-phase SAR data converter in accordance with various embodiments. Specifically, FIG. 3B shows the sequential steps undertaken in a single S/R/H quantization cycle for phase three (i.e., PH3 306) within a single stage of the ADC. For PH3 306, the sequence of operations unfolds as follows: R, H, S, R, H, S, R. For the purpose of this description, the process starts with the S mode, then proceeds with R, and follows with H.

In the S mode (Sample), the input switch, identified as S switch 142 in FIG. 2, captures or samples the incoming analog input signal at step 320. This sampling is conducted in synchrony with the state machine processing unit 202 to ensure timing accuracy. Concurrently, the bottom plates of the digital-to-analog converter (DAC) capacitors (C₁, C₂, up to C_{N}) are reset to their initial value at step 322. In an embodiment, this ensures that each capacitor starts with a known and consistent initial value. In an embodiment, this reset operation serves to clear any residual charges that may influence the accuracy of the subsequent conversion cycles. Resetting the DAC capacitors is executed under the control of state machine processing unit 202, which generates control signals 212 to coordinate this reset. The action ensures that any charge accumulation from previous operational phases, such as PH1 and PH2, does not affect the current sampling in PH3, thus maintaining the consistency of the analog-to-digital conversion process.

In the R mode, the R-switch 324 operates to establish a connection between the sampled signal and the circuit components constituting the comparator and DAC loop. In this configuration, the state machine processing unit 202 coordinates with the series of switched capacitors (C₁, C₂, up to C_{N}) and differential comparator 152 to initiate the successive approximation routine (SAR). In an embodiment, the comparator and DAC loop include differential comparator 152, amplifier 154, and the switched capacitors controlled by state machine processing unit 202. These components work collectively to perform successive approximation of the analog input signal. An N-step successive approximation algorithm is executed 326 to convert the analog signal into an N-bit digital output. If, for example, N equals 8, the state machine processing unit 202 performs eight cycles of approximation, each one refining one of the eight bits in the digital output, starting from the most significant bit (MSB) to the least significant bit (LSB). Upon completion of the N steps, a digital output is generated that approximates the original analog input. This digital output is then available for additional processing or analysis.

During the H mode, the H-switch 146 is engaged to apply 328 the analog residue value to an amplifier capacitive loop comprising amplifier 154 and capacitors C1, C2, up to CN. In an embodiment, this action serves to amplify the analog residue remaining on the digital-to-analog converter (DAC) 150. As amplifier 154 receives the analog residue, it amplifies the value by a predetermined amplification factor, for example, a factor of ‘A’, through its capacitive loop.

The amplified residue is channeled to the next sequential stage for further quantization and processing. For instance, if the current stage is stage 102, the amplified residue will be provided 330 to stage 104. This orchestration is governed by control signals 212 from the state machine processing unit 202, ensuring a transition between different operational phases and stages.

In the context of parallel processing across multiple operational phases, it is noteworthy that the sample(S) phase (PH1-S) of the subsequent stage aligns temporally with the Amplify/Hold (H) phase (PH1-H) of the current stage. This is made possible through a tuned timing diagram that governs the switching operations, enabling the system to maximize throughput and reduce idle times, further optimizing the efficiency of the conversion process.

While the timing for PH1-S in the subsequent stage occurs in tandem with the PH1-H of the current stage, the overall timing diagram across all stages remains substantially consistent, thereby streamlining the conversion process from analog to digital form.

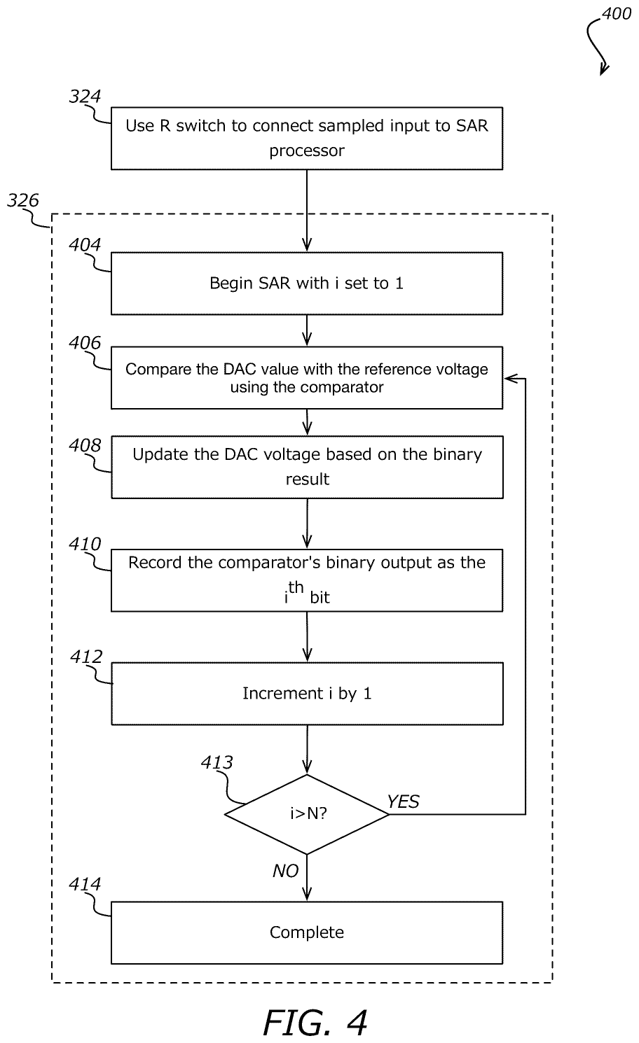

FIG. 4 illustrates example 400 of the binary search algorithm for the successive approximation register (SAR) quantization process in accordance with various embodiments. The process corresponds to step 326 elucidated in FIG. 3B, where the quantization of the analog signal occurs through a methodical approach. At step 404, the SAR process is initiated, with the variable ‘i’ established at a starting value of 1. This setting of ‘i’ serves as an initial reference point for the quantization cycle, allowing for a sequential examination of the binary values associated with the analog signal. Throughout this process, the state machine processing unit 202, as described in the context of FIG. 3B and elsewhere herein, is operable to orchestrate the operations, ensuring a seamless interaction between the components, such as the digital-to-analog converter (DAC) capacitors and differential comparator 152. By setting ‘i’ to 1, the system targets the most significant bit (MSB) first, laying the groundwork for the subsequent iterative steps of the SAR algorithm, where each iteration refines the digital representation of the original analog input.

At step 406, the system proceeds to compare the output value from the digital-to-analog converter (DAC) with a predetermined reference voltage. In an embodiment, this can be accomplished using the differential comparator 152.

At step 408, following the comparative evaluation at the prior step, the system adjusts the voltage value of the digital-to-analog converter (DAC). This adjustment is guided by the binary outcome from the differential comparator 152. If the DAC's output value was found to exceed the reference voltage, the system would alter the DAC to lower the voltage, whereas if the DAC's output was below the reference, the system would elevate the DAC voltage. This iterative refinement continues throughout the successive approximation process. The state machine processing unit 202, as introduced in FIG. 2 and FIG. 3B, orchestrates this update process, generating specific control signals (e.g., R₁) that modulate the switched capacitors (C₁, C₂, up to C_{N}) to achieve the desired DAC voltage setting.

At step 410, after obtaining the binary result from the differential comparator 152, the system captures this binary output as the specific bit at position ‘i’ in the resulting digital representation. As the successive approximation routine progresses, it sequentially identifies each bit, starting from the most significant bit (MSB) and progressing towards the least significant bit (LSB). For instance, if during the first iteration ‘i’ is set to 1, this step would record the first, or most significant, bit of the N-bit digital output. In the context of the entire algorithm, this recorded bit is integral to the formation of the digital representation of the analog signal. As described herein, state machine processing unit 202 coordinates this recording process.

At step 412, the variable ‘i’ is incremented by 1. This action shifts the focus sequentially to the next bit in the N-bit digital representation. This increment ensures that the successive approximation routine systematically evaluates and refines each bit.

At step 413, the system evaluates the current value of ‘i’ against the threshold ‘N,’ which denotes the total number of bits for the digital output. This comparison serves to determine whether the successive approximation process has addressed all the bits or if further iterations are necessary.

If the value of ‘i’ exceeds ‘N’, indicating that all the bits have been processed, the process loops back to step 406, preparing for another round of signal conversion.

Conversely, if ‘i’ is less than or equal to ‘N,’ indicating that there are still bits left to be processed in the current conversion cycle, the process advances to its completion at step 414. At this point, the analog signal has been fully quantized into its corresponding N-bit digital output, and the system stands ready for the next analog input or other subsequent operations.

In accordance with various embodiments various other functions may be provided in accordance with the various embodiments.

For example, in some aspects, the techniques described herein relate to a data converter, including: a receive path for receiving an analog input signal; a plurality of processing stages, including a first processing stage, a second processing stage, and a third processing stage, wherein each processing stage is configured to quantize a received input signal by a predetermined number of bits; wherein the first processing stage is configured to: receive the analog input signal, quantize the analog input signal to generate a first quantized signal, and determine a first analog residue signal based on a difference between sampled instances of the analog input signal and corresponding quantized values in the first quantized signal; wherein the second processing stage is configured to: receive the first analog residue signal, quantize the first analog residue signal to generate a second quantized signal, and determine a second analog residue signal based on a difference between a sampled signal of the first analog residue signal and a quantized version of the first analog residue signal; wherein the third processing stage is configured to: receive the second analog residue signal, quantize the second analog residue signal to generate a third quantized signal, and determine a third analog residue signal based on a difference between a sampled signal of the second analog residue signal and a quantized version of the second analog residue signal; and an output for providing a digital output signal that is a compilation of quantized values from the first quantized signal, the second quantized signal, and the third quantized signal; wherein the data converter employs a sequence of operational modes including a sampling mode, a successive approximation mode, and an amplify/hold mode to facilitate conversion of the analog input signal to the digital output signal.

In some aspects, the techniques described herein relate to a data converter, wherein the plurality of processing stages are coupled to a group of shared resources including an analog-to-digital converter (ADC) and an amplifier.

In some aspects, the techniques described herein relate to a data converter, further including: a state machine processing unit; and a memory device including instructions that, when executed by the state machine processing unit, enables the data converter to: process the analog input signal through the plurality of processing stages, each stage including a plurality of operational phases, including a first phase, a second phase, and a third phase, wherein each operational phase is configured to execute a sample mode, a successive approximation mode, and an amplify/hold mode in a predetermined sequence; and generate the digital output signal representative of the analog input signal.

In some aspects, the techniques described herein relate to a data converter, further including: a sample switch configured to capture an input analog signal and provide an output to a successive approximation switch and a differential comparator, wherein the successive approximation switch is operable to facilitate quantization of the input analog signal and provide an output to the analog-to-digital converter (ADC).

In some aspects, the techniques described herein relate to a data converter, further including: a digital-to-analog converter (DAC), operable to receive an output from the analog-to-digital converter (ADC) and calculate a difference between sampled and quantized signals.

In some aspects, the techniques described herein relate to a data converter, wherein the differential comparator is operable to evaluate the output from the digital-to-analog converter (DAC) to generate an output utilized by an amplify/hold switch.

In some aspects, the techniques described herein relate to a data converter, wherein the amplify/hold switch is connected to the amplifier, and wherein the amplifier is operable to amplify residue signals.

In some aspects, the techniques described herein relate to a data converter, wherein the state machine processing unit is operable to perform binary search quantization, generate control signals to coordinate operational modes for the plurality of operational phases, and adjust switched capacitors in response to feedback from a differential comparator.

In some aspects, the techniques described herein relate to a data converter, wherein the instructions, when executed by the state machine processing unit, further enable the data converter to: during the sample mode, sample the analog input signal with a sample switch to generate a sampled signal; during the successive approximation mode, establish a connection between the sampled signal and a comparator and a digital-to-analog converter (DAC) using an R-switch, and initiating a successive approximation routine under coordination of the state machine processing unit with a differential comparator to generate an N-bit digital output that approximates the analog input signal; and during the amplify/hold mode, route an analog residue value to an amplifier, amplify the analog residue value through the amplifier, and provide amplified residue to a subsequent stage for further processing.

In some aspects, the techniques described herein relate to a computer-implemented method, including: receiving an analog input signal via a receive path; obtaining the analog input signal at a first processing stage to: quantize the analog input signal, generate a first quantized signal, and determine a first analog residue signal based on a difference between sampled instances of the analog input signal and corresponding quantized values in the first quantized signal; obtaining the first analog residue signal through a second processing stage to: quantize the first analog residue signal, generating a second quantized signal, and determine a second analog residue signal based on a difference between a sampled signal of the first analog residue signal and a quantized version of the first analog residue signal; obtaining the second analog residue signal through a third processing stage to: quantize the second analog residue signal to generate a third quantized signal, and determine a third analog residue signal based on a difference between a sampled signal of the second analog residue signal and a quantized version of the second analog residue signal; and generating a digital output signal from quantized values of the first quantized signal, the second quantized signal, and the third quantized signal; wherein a sequence of operational modes including a sampling mode, a successive approximation mode, and an amplify/hold mode is utilized during conversion of the analog input signal to the digital output signal.

In some aspects, the techniques described herein relate to a computer-implemented method, further including: utilizing a group of shared resources including an analog-to-digital converter (ADC) and an amplifier to obtain the analog input signal at the first processing stage and the second processing stage.

In some aspects, the techniques described herein relate to a computer-implemented method, further including: processing the analog input signal through a plurality of operational phases, each phase including a sample mode, a successive approximation mode, and an amplify/hold mode; and generate the digital output signal representative of the analog input signal.

In some aspects, the techniques described herein relate to a computer-implemented method, wherein the obtaining of the analog input signal at the first processing stage involves, using a sample switch to capture the analog input signal; and providing a captured analog input signal to a successive approximation switch and a differential comparator, wherein the successive approximation switch facilities the quantization of the captured analog signal and directs an output to the analog-to-digital converter (ADC).

In some aspects, the techniques described herein relate to a computer-implemented method, further including: utilizing a digital-to-analog converter (DAC) to process an output from the analog-to-digital converter (ADC) and calculate a difference between sampled and quantized signals.

In some aspects, the techniques described herein relate to a computer-implemented method, wherein the differential comparator evaluates the output from the digital-to-analog converter (DAC) to generate an output that is processed by an amplify/hold switch.

In some aspects, the techniques described herein relate to a computer-implemented method, wherein the amplify/hold switch routes the output to an amplifier, and wherein the amplifier amplifies residue signals.

In some aspects, the techniques described herein relate to a computer-implemented method, further including: generating control signals to coordinate the sequence of operational modes for the plurality of operational phases, and adjusting switched capacitors based on feedback from a differential comparator.

In some aspects, the techniques described herein relate to a computer-implemented method, further including: during the sample mode, sampling the analog input signal with a sample switch to produce a sampled signal; during the successive approximation mode, establishing a connection between the sampled signal and a comparator and a digital-to-analog converter (DAC) using an R-switch, and initiating a successive approximation routine to generate an N-bit digital output approximating the analog input signal; and during the amplify/hold mode, routing an analog residue value to an amplifier, amplifying the analog residue value using the amplifier, and providing the amplified residue to a subsequent processing stage.

In some aspects, the techniques described herein relate to a non-transitory computer readable storage medium storing instructions that, when executed by at least one processor of a computing system, causes the computing system to: receive an analog input signal via a receive path; obtain the analog input signal at a first processing stage to: quantize the analog input signal, generate a first quantized signal, and determine a first analog residue signal based on a difference between sampled instances of the analog input signal and corresponding quantized values in the first quantized signal; obtain the first analog residue signal through a second processing stage to: quantize the first analog residue signal, generating a second quantized signal, and determine a second analog residue signal based on a difference between a sampled signal of the first analog residue signal and a quantized version of the first analog residue signal; obtain the second analog residue signal through a third processing stage to: quantize the second analog residue signal to generate a third quantized signal, and determine a third analog residue signal based on a difference between a sampled signal of the second analog residue signal and a quantized version of the second analog residue signal; and generate a digital output signal from quantized values of the first quantized signal, the second quantized signal, and the third quantized signal; wherein a sequence of operational modes including a sampling mode, a successive approximation mode, and an amplify/hold mode is utilized during conversion of the analog input signal to the digital output signal.

### Hardware Architecture

Generally, the techniques disclosed herein may be implemented on hardware or a combination of software and hardware. For example, they may be implemented in an operating system kernel, in a separate user process, in a library package bound into network applications, on a specially constructed machine, on an application-specific integrated circuit (ASIC), or on a network interface card.

Software/hardware hybrid implementations of at least some of the embodiments disclosed herein may be implemented on a programmable network-resident machine (which should be understood to include intermittently connected network-aware machines) selectively activated or reconfigured by a computer program stored in memory. Such computing devices may have multiple network interfaces that may be configured or designed to utilize different types of network communication protocols. A general architecture for some of these machines may be described herein in order to illustrate one or more exemplary means by which a given unit of functionality may be implemented. According to specific embodiments, at least some of the features or functionalities of the various embodiments disclosed herein may be implemented on one or more general-purpose computers associated with one or more networks, such as for example an end-user computer system, a client computer, a network server or other server system, a mobile computing device (e.g., tablet computing device, mobile phone, smartphone, laptop, or other appropriate computing device), a consumer electronic device, a music player, or any other suitable electronic device, router, switch, or other suitable device, or any combination thereof. In at least some embodiments, at least some of the features or functionalities of the various embodiments disclosed herein may be implemented in one or more virtualized computing environments (e.g., network computing clouds, virtual machines hosted on one or more physical computing machines, or other appropriate virtual environments).

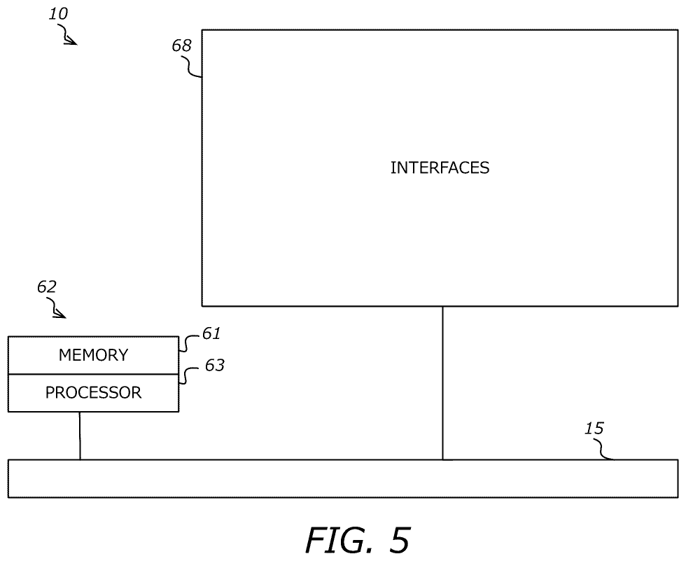

FIG. 5 illustrates an example of an exemplary computing device 10 that can be utilized in accordance with various embodiments. Computing device 10 includes a master central processing unit (CPU) 62, interfaces 68, and a bus 15 (e.g., a PCI bus). When acting under the control of appropriate software or firmware, the CPU 62 is responsible for numerous tasks, at least some of which relate to network management. It preferably accomplishes all these functions under the control of software including an operating system and any appropriate applications software. CPU 62 may include one or more processors 63. In an alternative embodiment, processor 63 is specially designed hardware for controlling the operations of computing device 10. In a specific embodiment, a memory 61 (such as non-volatile RAM and/or ROM) also forms part of CPU 62. However, there are many different ways in which memory could be coupled to the system.

The interfaces 68 are typically provided as interface cards (sometimes referred to as “line cards”). Generally, they control the sending and receiving of data packets over the network and sometimes support other peripherals used with the router. Among the interfaces that may be provided are Ethernet interfaces, frame relay interfaces, cable interfaces, DSL interfaces, token ring interfaces, and the like. In addition, various very high-speed interfaces may be provided such as fast token ring interfaces, wireless interfaces, Ethernet interfaces, Gigabit Ethernet interfaces, ATM interfaces, HSSI interfaces, POS interfaces, FDDI interfaces and the like. Generally, these interfaces may include ports appropriate for communication with the appropriate media. In some cases, they may also include an independent processor and, in some instances, volatile RAM. The independent processors may control such communications intensive tasks as packet switching, media control, and management. By providing separate processors for the communication's intensive tasks, these interfaces allow the master microprocessor 62 to efficiently perform routing computations, network diagnostics, security functions, etc.

Although the system shown in FIG. 5 is one specific computing device of the present invention, it is by no means the only computing device architecture on which the present invention can be implemented. For example, an architecture having a single processor that handles communications as well as routing computations etc. is often used. Further, other types of interfaces and media could also be used with the router.

Regardless of the computing device's configuration, it may employ one or more memories, or memory modules (including memory 61) configured to store program instructions for the general-purpose network operations and mechanisms for roaming, route optimization and routing functions described herein. The program instructions may control the operation of an operating system and/or one or more applications, for example. The memory or memories may also be configured to store tables such as mobility binding, registration, and association tables, etc.

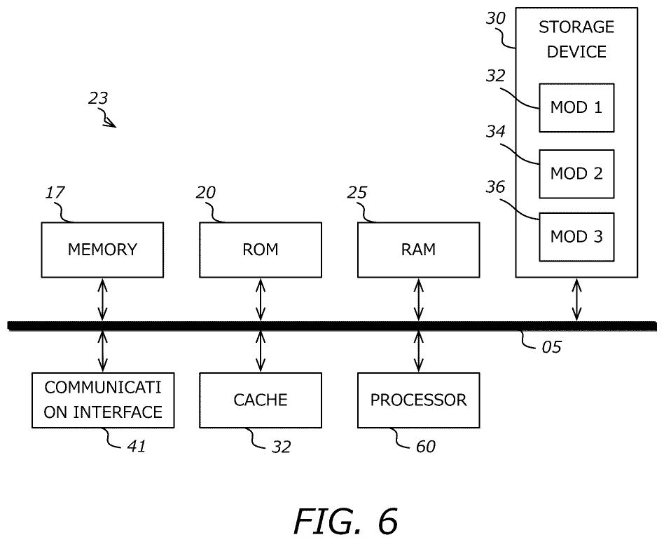

FIG. 6 illustrates an example of exemplary possible system embodiments, such a system making up computing device 10 of FIG. 5. The more appropriate embodiment will be apparent to those of ordinary skill in the art when practicing the present technology. Persons of ordinary skill in the art will also readily appreciate that other system embodiments are possible. FIG. 6 illustrates a conventional system bus computing system architecture 23 wherein the components of the system are in electrical communication with each other using a bus 05.

Exemplary system xx00 includes a processing unit (CPU or processor) 60 and a system bus 05 that couples various system components including the system memory 17, such as read-only memory (ROM) 20 and random-access memory (RAM) 25, to the processor 60. The system 23 can include a cache of high-speed memory connected directly with, in close proximity to, or integrated as part of the processor 60. The system can copy data from system memory 17 and/or the storage device 30 to the cache 33 for quick access by the processor 60. In this way, the cache can provide a performance boost that avoids processor 60 delays while waiting for data. These and other modules can control or be configured to control the processor 60 to perform various actions. Other system memory 17 may be available for use as well. The memory 17 can include multiple different types of memory with different performance characteristics. The processor 60 can include any general-purpose processor and a hardware module or software module, such as module 1 32, module 2 34, and module 3 36 stored in storage device 30, configured to control the processor 60 as well as a special-purpose processor where software instructions are incorporated into the actual processor design. The processor 60 may essentially be a completely self-contained computing system, containing multiple cores or processors, a bus, memory controller, cache, etc. A multi-core processor may be symmetric or asymmetric. The processor can be implemented with one or more virtual processors, as well as any combination of CPUs and virtual processors.

The communications interface 41 can generally govern and manage the user input and system output. There is no restriction on operating on any particular hardware arrangement, and therefore the basic features here may easily be substituted for improved hardware or firmware arrangements as they are developed.

Storage device 30 is a non-volatile memory and can be a hard disk or other types of computer readable media which can store data that are accessible by a computer, such as magnetic cassettes, flash memory cards, solid state memory devices, digital versatile disks, cartridges, random access memories (RAMs) 25, read-only memory (ROM) 20, any other memory chip or cartridge, or any other medium from which a computer can read. Instructions may further be transmitted or received using a transmission medium. The term “transmission medium” may include any tangible or intangible medium that is capable of storing, encoding or carrying instructions for execution by the machine, and includes digital or analog communications signals or another intangible medium to facilitate communication of such instructions. Transmission media includes coaxial cables, copper wire, and fiber optics, including wires that comprise bus 05 for transmitting a computer data signal.

The storage device 30 can include software modules 32, 34, 36 for controlling the processor 60. Other hardware or software modules are contemplated. The storage device 30 can be connected to the system bus 05. In one aspect, a hardware module that performs a particular function can include the software component stored in a computer-readable medium in connection with the necessary hardware components, such as the processor 60, bus 05, and so forth, to carry out the function.

### Additional Considerations

One or more different embodiments may be described in the present application. Further, for one or more of the embodiments described herein, numerous alternative arrangements may be described; it should be appreciated that these are presented for illustrative purposes only and are not limiting of the embodiments contained herein or the claims presented herein in any way. One or more of the arrangements may be widely applicable to numerous embodiments, as may be readily apparent from the disclosure. In general, arrangements are described in sufficient detail to enable those skilled in the art to practice one or more of the embodiments, and it should be appreciated that other arrangements may be utilized and that structural, logical, software, electrical and other changes may be made without departing from the scope of the embodiments. Particular features of one or more of the embodiments described herein may be described with reference to one or more particular embodiments or figures that form a part of the present disclosure, and in which are shown, by way of illustration, specific arrangements of one or more of the aspects. It should be appreciated, however, that such features are not limited to usage in the one or more particular embodiments or figures with reference to which they are described. The present disclosure is neither a literal description of all arrangements of one or more of the embodiments nor a listing of features of one or more of the embodiments that must be present in all arrangements.

Headings of sections provided in this patent application and the title of this patent application are for convenience only and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible embodiments and in order to more fully illustrate one or more embodiments. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the embodiments, and does not imply that the illustrated process is preferred. Also, steps are generally described once per aspect, but this does not mean they must occur once, or that they may only occur once each time a process, method, or algorithm is carried out or executed. Some steps may be omitted in some embodiments or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other embodiments need not include the device itself.

Techniques and mechanisms described or referenced herein will sometimes be described in singular form for clarity. However, it should be appreciated that particular embodiments may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various embodiments in which, for example, functions may be executed out of order from that shown or discussed, including substantially concurrently or in reverse order, depending on the functionality involved, as would be understood by those having ordinary skill in the art.

The detailed description set forth herein in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive “or” and not to an exclusive “or.” For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

Upon reading this disclosure, those of skill in the art will appreciate still additional alternative structural and functional designs for a system and a process related to analog-to-digital converters (ADCs), specifically in the context of a multi-phase pipeline Successive Approximation Register (SAR) ADC architecture. Thus, while particular embodiments and applications have been illustrated and described, it is to be understood that the disclosed embodiments are not limited to the precise construction and components disclosed herein. Various apparent modifications, changes and variations may be made in the arrangement, operation and details of the method and apparatus disclosed herein without departing from the spirit and scope defined in the appended claims.

For clarity of explanation, in some instances, the present technology may be presented as including individual functional blocks including functional blocks comprising devices, device components, steps or routines in a method embodied in software, or combinations of hardware and software.

In some embodiments, the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer-readable media. Such instructions can comprise, for example, instructions and data which cause or otherwise configure a general-purpose computer, special purpose computer, or special purpose processing device to perform a certain function or group of functions. In some examples, hard-wired circuitry may be used in place of or in combination with software instructions for implementation. Portions of computer resources used can be accessible over a network. The computer-executable instructions may be, for example, binaries, intermediate format instructions such as assembly language, firmware, or source code. Examples of computer-readable media that may be used to store instructions, information used, and/or information created during methods according to described examples include magnetic or optical disks, flash memory, USB devices provided with non-volatile memory, networked storage devices, and so on.

Devices implementing methods according to these disclosures can comprise hardware, firmware and/or software, and can take any of a variety of form factors. Typical examples of such form factors include laptops, smartphones, small form factor personal computers, personal digital assistants, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are means for providing the functions described in these disclosures.

Although a variety of examples and other information was used to explain aspects within the scope of the appended claims, no limitation of the claims should be implied based on particular features or arrangements in such examples, as one of ordinary skill would be able to use these examples to derive a wide variety of implementations. Further and although some subject matter may have been described in language specific to examples of structural features and/or method steps, it is to be understood that the subject matter defined in the appended claims is not necessarily limited to these described features or acts. For example, such functionality can be distributed differently or performed in components other than those identified herein. Rather, the described features and steps are disclosed as examples of components of systems and methods within the scope of the appended claims.

The various embodiments can be implemented in a wide variety of operating environments, which in some cases can include one or more user electronic devices, integrated circuits, chips, and computing devices—each with the proper configuration of hardware, software, and/or firmware as presently disclosed. Such a system can also include a number of the above exemplary systems working together to perform the same function disclosed herein—to filter tones from a mixed signal using novel integrated circuits in a communications network.

Most embodiments utilize at least one communications network that would be familiar to those skilled in the art for supporting communications using any of a variety of commercially available protocols, such as TCP/IP, FTP, UPnP, NFS, and CIFS. The communications network can be, for example, a cable network, a local area network, a wide-area network, a virtual private network, the Internet, an intranet, an extranet, a public switched telephone network, an infrared network, a wireless network and any combination thereof.

The environment can include a variety of data stores and other memory and storage media as discussed above—including at least a buffer. These storage components can reside in a variety of locations, such as on a storage medium local to (and/or resident in) one or more of the computers or remote from any or all of the computers across the network. In a particular set of embodiments, the information may reside in a storage-area network (SAN) familiar to those skilled in the art. Similarly, any necessary files for performing the functions attributed to the computers, servers, or other computing devices may be stored locally and/or remotely, as appropriate. Where a system includes computerized devices, each such device can include hardware elements that may be electrically coupled via a bus, the elements including, for example, at least one central processing unit (CPU), at least one input device (e.g., a mouse, keyboard, controller, touch-sensitive display element or keypad) and at least one output device (e.g., a display device, printer or speaker). Such a system may also include one or more storage devices, such as disk drives, optical storage devices and solid-state storage devices such as random-access memory (RAM) or read-only memory (ROM), as well as removable media devices, memory cards, flash cards, etc.

Such devices can also include a computer-readable storage media reader, a communications device (e.g., a modem, a network card (wireless or wired), an infrared communication device) and working memory as described above. The computer-readable storage media reader can be connected with or configured to receive, a computer-readable storage medium representing remote, local, fixed and/or removable storage devices as well as storage media for temporarily and/or more permanently containing, storing, transmitting and retrieving computer-readable information. The system and various devices also typically will include a number of software applications, modules, services or other elements located within at least one working memory device, including an operating system and application programs such as a client application or Web browser. It should be appreciated that alternate embodiments may have numerous variations from that described above. For example, customized hardware might also be used, and/or particular elements might be implemented in hardware, software (including portable software, such as applets) or both. Further, connection to other computing devices such as network input/output devices may be employed.

Storage media and other non-transitory computer readable media for containing code, or portions of code, can include any appropriate media known or used in the art, such as but not limited to volatile and non-volatile, removable and non-removable media implemented in any method or technology for storage of information such as computer readable instructions, data structures, program modules or other data, including RAM, ROM, EEPROM, flash memory or other memory technology, CD-ROM, digital versatile disk (DVD) or other optical storage, magnetic cassettes, magnetic tape, magnetic disk storage or other magnetic storage devices or any other medium which can be used to store the desired information and which can be accessed by a system device. Based on the disclosure and teachings provided herein, a person of ordinary skill in the art will appreciate other ways and/or methods to implement the various embodiments.

The specification and drawings are, accordingly, to be regarded in an illustrative rather than a restrictive sense. It will, however, be evident that various modifications and changes may be made thereunto without departing from the broader spirit and scope of the invention as set forth in the claims.

What is claimed is:

1. A data converter, comprising:
a receive path for receiving an analog input signal;
a plurality of processing stages, including a first processing stage, a second processing stage, and a third processing stage, wherein each processing stage is configured to quantize a received input signal by a predetermined number of bits;
wherein the first processing stage is configured to:
receive the analog input signal,
quantize the analog input signal to generate a first quantized signal, and
determine a first analog residue signal based on a difference between sampled instances of the analog input signal and corresponding quantized values in the first quantized signal;
wherein the second processing stage is configured to:
receive the first analog residue signal,
quantize the first analog residue signal to generate a second quantized signal, and
determine a second analog residue signal based on a difference between a sampled signal of the first analog residue signal and a quantized version of the first analog residue signal;
wherein the third processing stage is configured to:
receive the second analog residue signal,
quantize the second analog residue signal to generate a third quantized signal, and
determine a third analog residue signal based on a difference between a sampled signal of the second analog residue signal and a quantized version of the second analog residue signal; and
an output for providing a digital output signal that is a compilation of quantized values from the first quantized signal, the second quantized signal, and the third quantized signal;
wherein the data converter employs a sequence of operational modes including a sampling mode, a successive approximation mode, and an amplify/hold mode to facilitate conversion of the analog input signal to the digital output signal.

2. The data converter of claim 1, wherein the plurality of processing stages are coupled to a group of shared resources comprising an analog-to-digital converter (ADC) and an amplifier.

3. The data converter of claim 2, further comprising:
a state machine processing unit; and
a memory device including instructions that, when executed by the state machine processing unit, enables the data converter to:
process the analog input signal through the plurality of processing stages, each stage comprising a plurality of operational phases, including a first phase, a second phase, and a third phase, wherein each operational phase is configured to execute a sample mode, a successive approximation mode, and an amplify/hold mode in a predetermined sequence; and
generate the digital output signal representative of the analog input signal.

4. The data converter of claim 3, further comprising:
a sample switch configured to capture an input analog signal and provide an output to a successive approximation switch and a differential comparator, wherein the successive approximation switch is operable to facilitate quantization of the input analog signal and provide an output to the analog-to-digital converter (ADC).

5. The data converter of claim 4, further comprising:
a digital-to-analog converter (DAC), operable to receive an output from the analog-to-digital converter (ADC) and calculate a difference between sampled and quantized signals.

6. The data converter of claim 5, wherein the differential comparator is operable to evaluate the output from the digital-to-analog converter (DAC) to generate an output utilized by an amplify/hold switch.

7. The data converter of claim 6, wherein the amplify/hold switch is connected to the amplifier, and wherein the amplifier is operable to amplify residue signals.

8. The data converter of claim 3, wherein the state machine processing unit is operable to perform binary search quantization, generate control signals to coordinate operational modes for the plurality of operational phases, and adjust switched capacitors in response to feedback from a differential comparator.

9. The data converter of claim 3, wherein the instructions, when executed by the state machine processing unit, further enable the data converter to:
during the sample mode, sample the analog input signal with a sample switch to generate a sampled signal;
during the successive approximation mode, establish a connection between the sampled signal and a comparator and a digital-to-analog converter (DAC) using an R-switch, and initiating a successive approximation routine under coordination of the state machine processing unit with a differential comparator to generate an N-bit digital output that approximates the analog input signal; and
during the amplify/hold mode, route an analog residue value to an amplifier, amplify the analog residue value through the amplifier, and provide amplified residue to a subsequent stage for further processing.

10. A computer-implemented method, comprising:
receiving an analog input signal via a receive path;
obtaining the analog input signal at a first processing stage to:
quantize the analog input signal,
generate a first quantized signal, and
determine a first analog residue signal based on a difference between sampled instances of the analog input signal and corresponding quantized values in the first quantized signal;
obtaining the first analog residue signal through a second processing stage to:
quantize the first analog residue signal, generating a second quantized signal, and
determine a second analog residue signal based on a difference between a sampled signal of the first analog residue signal and a quantized version of the first analog residue signal;
obtaining the second analog residue signal through a third processing stage to:
quantize the second analog residue signal to generate a third quantized signal, and
determine a third analog residue signal based on a difference between a sampled signal of the second analog residue signal and a quantized version of the second analog residue signal; and
generating a digital output signal from quantized values of the first quantized signal, the second quantized signal, and the third quantized signal;
wherein a sequence of operational modes including a sampling mode, a successive approximation mode, and an amplify/hold mode is utilized during conversion of the analog input signal to the digital output signal.

11. The computer-implemented method of claim 10, further comprising:
utilizing a group of shared resources comprising an analog-to-digital converter (ADC) and an amplifier to obtain the analog input signal at the first processing stage and the second processing stage.

12. The computer-implemented method of claim 11, further comprising:
processing the analog input signal through a plurality of operational phases, each phase including a sample mode, a successive approximation mode, and an amplify/hold mode; and
generate the digital output signal representative of the analog input signal.

13. The computer-implemented method of claim 12, wherein obtaining of the analog input signal at the first processing stage involves,
using a sample switch to capture the analog input signal; and
providing a captured analog input signal to a successive approximation switch and a differential comparator, wherein the successive approximation switch facilitates quantization of obtained analog signal and directs an output to the analog-to-digital converter (ADC).

14. The computer-implemented method of claim 13, further comprising:
utilizing a digital-to-analog converter (DAC) to process an output from the analog-to-digital converter (ADC) and calculate a difference between sampled and quantized signals.

15. The computer-implemented method of claim 14, wherein the differential comparator evaluates the output from the digital-to-analog converter (DAC) to generate an output that is processed by an amplify/hold switch.

16. The computer-implemented method of claim 15, wherein the amplify/hold switch routes the output to an amplifier, and wherein the amplifier amplifies residue signals.

17. The computer-implemented method of claim 12, further comprising:
generating control signals to coordinate the sequence of operational modes for the plurality of operational phases, and adjusting switched capacitors based on feedback from a differential comparator.

18. The computer-implemented method of claim 12, further comprising:
during the sample mode, sampling the analog input signal with a sample switch to produce a sampled signal;
during the successive approximation mode, establishing a connection between the sampled signal and a comparator and a digital-to-analog converter (DAC) using an R-switch, and initiating a successive approximation routine to generate an N-bit digital output approximating the analog input signal; and
during the amplify/hold mode, routing an analog residue value to an amplifier, amplifying the analog residue value using the amplifier, and providing the amplified residue to a subsequent processing stage.

19. The computer-implemented method of claim 10, wherein the sequence of operational modes is adjusted based on characteristics of the analog input signal to optimize a performance metric associated with the digital output, the performance metric quantifying one of a level of accuracy or efficiency.

20. A non-transitory computer readable storage medium storing instructions that, when executed by at least one processor of a computing system, causes the computing system to:
receive an analog input signal via a receive path;
obtain the analog input signal at a first processing stage to:
quantize the analog input signal,
generate a first quantized signal, and
determine a first analog residue signal based on a difference between sampled instances of the analog input signal and corresponding quantized values in the first quantized signal;
obtain the first analog residue signal through a second processing stage to:
quantize the first analog residue signal, generating a second quantized signal, and
determine a second analog residue signal based on a difference between a sampled signal of the first analog residue signal and a quantized version of the first analog residue signal;
obtain the second analog residue signal through a third processing stage to:
quantize the second analog residue signal to generate a third quantized signal, and
determine a third analog residue signal based on a difference between a sampled signal of the second analog residue signal and a quantized version of the second analog residue signal; and
generate a digital output signal from quantized values of the first quantized signal, the second quantized signal, and the third quantized signal;
wherein a sequence of operational modes including a sampling mode, a successive approximation mode, and an amplify/hold mode is utilized during conversion of the analog input signal to the digital output signal.
